(19) United States
(12) Patent Application Publication
(10) Pub. No.: US 2025/0306154 A1
(43) Pub. Date: Oct. 2, 2025

(54) PROVIDING A FINAL MOTION CORRECTED IMAGE DATASET BASED ON MAGNETIC RESONANCE DATA AND PROVIDING AT LEAST ONE TRAINED MACHINE LEARNING MODEL

(71) Applicant: Siemens Healthineers AG, Forchheim (DE)

(72) Inventors: Daniel Polak, Erlangen (DE); Marcel Dominik Nickel, Herzogenaurach (DE); Stephen Farman Cauley, Winchester, MA (US); Daniel Nicolas Splitthoff, Uttenreuth (DE); Bryan Clifford, Belmont, MA (US)

(21) Appl. No.: 19/087,833

(22) Filed: Mar. 24, 2025

(30) Foreign Application Priority Data
Mar. 28, 2024 (EP) 24167495

(51) Int. Cl. G01R 33/565; G01R 33/56; G06T 7/00; G06T 7/20; G06T 11/00

(52) U.S. Cl. CPC G01R 33/56509; G01R 33/5608; G06T 7/0002; G06T 7/20; G06T 11/006; G06T 11/008; G06T 2207/10088; G06T 2207/20056; G06T 2207/20081; G06T 2207/30168; G06T 2211/424; G06T 2211/441

(57) ABSTRACT

A computer-implemented method for providing a final motion corrected image dataset includes: receiving magnetic resonance data; determining a first motion corrected image dataset by solving a first optimization problem, wherein the first optimization problem depends on the magnetic resonance data and on motion data, and wherein the motion data concerns a movement of an object during the acquisition of the magnetic resonance data; processing the first motion corrected image dataset by an algorithm for image quality improvement to provide a processed image dataset; determining a second motion corrected image dataset by solving a second optimization problem that depends on the magnetic resonance data, on the motion data and on the processed image dataset, and either providing the second motion corrected image dataset as the final motion corrected image dataset or determining the provided final motion corrected image dataset based on the second motion corrected image dataset.

The present patent document claims the benefit of European Patent Application Ser. No. 24/167,495, filed Mar. 28, 2024, which is hereby incorporated by reference in its entirety.

### TECHNICAL FIELD

The disclosure concerns a computer-implemented method for providing a final motion corrected image dataset based on magnetic resonance data concerning an object (e.g., an inanimate object and/or a person/patient). Additionally, the disclosure concerns a computer-implemented method for providing at least one trained machine learning model, a data processing system, a computer program, and a computer-readable medium.

### BACKGROUND

In an era of rising medical imaging utilization, (e.g., for regular magnetic resonance screenings for Alzheimer's drug treatment), and increasing use of quantitative disease biomarkers and clinical support systems, (e.g., of brain morphometry and hemorrhage, edema and tumor identification and/or segmentation), there is high demand for high-quality, fast, and reproducible magnetic resonance imaging techniques. Motion during the image data acquisition remains one of the largest sources of image quality degradation, e.g., in patients with neuro-degenerative diseases. This may negatively affect the radiologist's image interpretation and/or diagnosis and/or affect the results of automated post-processing algorithms.

Deep learning image reconstruction has enabled reduced scan times while maintaining a high image quality and is now widely accepted in clinical settings. While faster scanning has been associated with a reduced likelihood of patient motion, it cannot solve the motion problem completely. A variety of retrospective motion correction techniques have been proposed:

Cordero-Grande L, Hughes E J, Hutter J, et al., “Three-Dimensional Motion Corrected Sensitivity Encoding Reconstruction for Multi-Shot Multi-Slice MRI: Application to Neonatal Brain Imaging,” Magnetic Resonance in Medicine 2018; 79:1365-1376, suggests using a combination of Sensitivity Encoding (SENSE) and a motion forward model (SENSE+motion). Estimating the motion trajectory and the motion-free image is achieved by minimizing the deviation between the physics model prediction and the acquired k-space data.

To avoid a computationally costly joint optimization, the Scout accelerated motion estimation and reduction (SAMER) technique is suggested in Polak D, Splitthoff D N, Clifford B, et al., “Scout accelerated motion estimation and reduction (SAMER),” Magn Reson Med. 2022; 87:163-178, and Polak D, Hossbach J, Splitthoff D N, et al., “Motion guidance lines for robust data consistency-based retrospective motion correction in 2D and 3D MRI.” Magn Reson Med. 2023; 1-14. In this technique, additional k-space encoding lines, called motion guidance lines, and/or an ultra-fast scout scan are acquired and used as a prior to guide the motion search. This facilitates very rapid trajectory estimation in ˜1 sec/shot. Once all motion parameters have been estimated, a SENSE+motion reconstruction is performed to obtain the motion mitigated image.

While the discussed approaches for retrospective motion compensation may provide a very good image quality at relatively low processing cost, when the k-space sampling is sufficiently dense, further accelerating the imaging sequence by, e.g., skipping a larger number of k-space points, may lead to a notable degradation of the image quality and of the reproducibility and robustness of the imaging.

### SUMMARY AND DESCRIPTION

The disclosure is therefore based on further improving the quality, robustness, and reproducibility of a retrospective motion compensation, in particular when an imaging sequence with highly undersampled data acquisition is used.

The scope of the present disclosure is defined solely by the appended claims and is not affected to any degree by the statements within this summary. The present embodiments may obviate one or more of the drawbacks or limitations in the related art.

The problem is solved by a computer-implemented method for providing a final motion corrected image dataset based on magnetic resonance data concerning an object (e.g., an inanimate object and/or a person/patient). The method includes receiving magnetic resonance data and determining a first motion corrected image dataset by solving a first optimization problem, wherein the first optimization problem depends on the magnetic resonance data and on motion data, and wherein the motion data concerns a movement of the object during the acquisition of the magnetic resonance data. The method further includes processing the first motion corrected image dataset by an algorithm for image quality improvement to provide a processed image dataset and determining a second motion corrected image dataset by solving a second optimization problem that depends on the magnetic resonance data, on the motion data, and on the processed image dataset. The method further includes either providing the second motion corrected image dataset as the final motion corrected image dataset or determining the provided final motion corrected image dataset based on the second motion corrected image dataset.

As described herein, by using multiple motion correction acts with an intermediate application of an algorithm for image quality improvement, the quality, robustness, and reproducibility of a retrospective motion compensation may be noticeably improved. The algorithm for image quality improvement may at least partially compensate the effects of high undersampling, e.g., of a sparse k-space sampling, e.g., noise amplification, residual aliasing artifacts, etc.

As will be discussed in more detail later, the algorithm for image quality improvement may be a trained model that is based on machine learning. Such trained models are especially suited to compensate the effects of a sparse k-space sampling. It was found that a quite notable improvement of the image quality may be achieved, e.g., when multiple iterations of the motion compensation with an intermediate image quality improvement act are performed, as will be discussed in more detail below.

The method allows for a retrospective motion correction and therefore for a motion correction that may be performed after the completion of the acquisition of the magnetic resonance data. The magnetic resonance data may be based on a parallel imaging technique that uses signals from multiple receiver coils to reduce imaging time. One of the more common parallel imaging techniques is the Sensitivity Encoding (SENSE) technique. This technique may be combined with a retrospective motion compensation, e.g., with the method. Such a combination may be called “SENSE plus motion forward model” or “SENSE+motion.”

The term “motion corrected image dataset” may refer to the output of an algorithm, which is configured to correct and/or compensate a motion of the object, regardless of whether the input data of this algorithm actually concerns a moving object. The term may refer to the respective result of the first and second optimization algorithm and to the result of the respective further optimization algorithm, discussed in greater detail below. The term “motion corrected image dataset” may therefore include cases in which the input data of the respective algorithm is not actually affected by motion. The term “motion corrected image dataset” may therefore also be understood to mean “potentially motion corrected image dataset.”

In certain examples, the motion data may be determined from magnetic resonance data that is provided by an imaging sequence, e.g., by a multi-shot, multi-slice spin echo sequence. This does however require to iteratively solve two partial optimization problems, namely the optimization of an approximate motion corrected image dataset based on previously determined approximate motion data and the optimization of the approximate motion data based on a previously determined approximate motion corrected image dataset.

Because such an alternating determination of motion data and a respective motion corrected image is highly computationally expensive, a more computationally efficient approach called “Scout accelerated motion estimation and reduction” (SAMER) is disclosed. In these examples, the motion data is determined from specific parts of the magnetic resonance data, e.g., from a low-resolution scout scan and/or the motion guidance lines. The measurement sequence, on which the magnetic resonance data is based, may be designed in such a way that the scout scan or the respective motion guidance lines for the respective shot are acquired in a sufficiently short time interval, wherein any motion of the object during that time interval may be neglected.

Alternatively, or additionally, any method for determining or tracking motion of an object (e.g., an inanimate object and/or a person/patient) may be used to determine the motion data. Possible sources for the motion data are an optical tracking of markers attached to the object, an evaluation of image data, (e.g., of three-dimensional image data depicting the object), motion sensors attached to the object, the evaluation of the magnetic resonance data, and/or other sensor data by a trained machine learning model, etc. The motion data or sensor data on which the motion data is based may be received with the magnetic resonance data. The determination of the motion data based on the magnetic resonance data or on specific parts of this magnetic resonance data, as discussed above, may advantageously be performed, because no additional sensors, markers, etc., are needed in this process.

The magnetic resonance data may be received directly from a magnetic resonance tomograph, read-out from a database, provided by a different routine or program running on the same device that implements the method or received from different device, etc.

Optionally, it is possible to perform a further processing of the final motion corrected image dataset, e.g., to perform a noise reduction, a contrast modification, and/or an edge enhancement. In particular, the method may be used to process magnetic resonance data in the context of brain imaging, but also in the context of imaging other body parts.

The term “solving an optimization problem” is to be understood to include an approximate solution, e.g., a solution that is reached after a stopping condition is met in an iterative solver, e.g., after a given number of iterations were performed or once an approximate solution changes less than a threshold between iterations.

The determination of the final motion corrected image dataset based on the second motion corrected image dataset may include at least one iteration of the following group of acts: processing a respective input motion corrected image dataset by the algorithm for image quality improvement or by a respective further algorithm for image quality improvement for the respective iteration to provide a respective further processed image dataset for the respective iteration, wherein the second motion corrected image dataset is used as the input motion corrected image dataset in the first iteration and wherein a respective output motion corrected image dataset determined during the previous iteration is used as the respective input motion corrected image dataset for the respective iteration in all iterations after the first iteration; and determining a respective output motion corrected image dataset for the respective iteration by solving a respective further optimization problem that depends on the magnetic resonance data, on the motion data and on the respective further processed image dataset for the respective iteration, wherein the output motion corrected image dataset determined in the last one of the iterations is provided as the final motion corrected image dataset.

Increasing the number of iterations may further improve the quality of the final motion corrected image dataset and/or, e.g., allow for an even sparser sampling of the k-space and therefore an even faster image acquisition while keeping the image quality approximately constant.

In certain examples, at least two or at least three iterations of the previously discussed group of acts, and therefore at least three or at least four iterations of an image quality improvement followed by a motion compensation, are used. A relatively low number of iterations, e.g., less than six or less than ten iterations of the group of acts, may in particular be sufficient, when SAMER or a different technique using a robust source of motion data is used. When the motion data is determined from normal magnetic resonance data without the use of the fast scout measurement or dedicated motion guidance lines, it may be advantageous to use twenty or more iterations of the group of acts.

In particular, when the same algorithm for image quality improvement is used in each iteration, multiple iterations may be implemented as a loop, wherein each iteration of the loop uses the output of the previous iteration as its input. When the algorithm for image quality improvement is implemented as a trained machine learning model, it may be advantageous to use an end to the end training including all of the iterations that may be performed when using the model. When the iterations are implemented as a loop, this may require the training of a recurrent model, e.g. of a recurrent neural network. Because a robust training of recurrent models may be more challenging than the training of, e.g., a pure feed forward network, the loop may be unrolled, leading to separate implementation of each iteration. Such an unrolling may especially be advantageous when a relatively low number of iterations is used, which may be sufficient when the SAMER technique is used, as discussed above.

An unrolling of such a loop and therefore the separate implementation of each iteration of the group of acts also allows for an easy implementation of the use of different further algorithms for image quality improvement for each iteration or for at least some of the iterations. When the respective algorithm is implemented as a trained machine learning model, it may be possible that the same basic algorithm is trained to implement the different algorithms for image quality improvement that are used in the different iterations. In this case, the different further algorithms may use the same architecture of the machine learning model and just differ in their parametrization. It is however also possible to use different architectures or even a different types of machine learning algorithms in different iterations. It may be possible to use a U-Net in the first couple of iterations and a transformer in the last iteration or in the last couple of iterations.

The second optimization problem may minimize a weighted sum of a first summand and a second summand by varying the second motion corrected image dataset, wherein the first summand is a measure for an inconsistency between the second motion corrected image dataset and the magnetic resonance data, wherein this measure is determined under the assumption that the motion data describes the movement of the object during the acquisition of the magnetic resonance data, and wherein the second summand is a measure for an inconsistency between the second motion corrected image dataset and the processed image dataset.

During the minimization of this weighted sum, the second summand induces a similarity of the second motion corrected image dataset to the processed image dataset and may therefore, e.g., reduce noise and/or reduce the formation of artifacts that may result from an undersampling of the k-space in the magnetic resonance data. Because the first summand does enforce a high consistency of the second motion corrected image dataset with the magnetic resonance data and of the motion data, the optimization is designed to find solutions that are consistent with the actual measurement while at the same time minimizing issues due to an undersampling or other influences that negatively impact the image quality.

An exemplary formulation for the first summand is now discussed for the case of a multi-shot acquisition, wherein the motion data describes a rigid-body motion of the object with respect to the magnetic resonance device. Using a motion forward model, the relationship between the motion free image x and the multi-channel k-space data sᵢ acquired for a given shot i may be given using an encoding operator E_{θ}_{ᵢ} that depends on a motion path θᵢ for the given shot i:

$${s}_{i} = {E}_{{θ}_{i}} x = {M}_{i} {FCT}_{{θ}_{i}} {R}_{{θ}_{i}} x ,$$

In the example, T_{θ}_{ᵢ} describes the translations and R_{θ}_{ᵢ} the rotations given by the motion data for the given shot i. The operator C encodes the coil sensitivity maps and the operator F performs a Fourier transform. An undersampling mask Mᵢ may be used to describe the undersampling in the k-space.

The encoding operator E_{θ}_{ᵢ} used in the example corresponds to the encoding operator. In certain examples, other formulations of the encoding operator may also be used to formulate an encoding operator that include a spatial sampling mask. While the translations and rotations are performed in image space in the example, all or some of the transformations and/or rotations may also be performed in k-space or may be implemented as part of the Fourier-transformation by using a non-uniform Fourier-transform.

When each shot includes motion guidance lines and/or when a low-resolution scout scan \tilde{x} may be considered to be approximately motion free, an actual motion path \hat{θ}ᵢ for the respective shot i may be determined as follows:

$$[ {\hat{θ}}_{i} ] = arg {min}_{{θ}_{i}} {‖ {E}_{{θ}_{i}} \tilde{x} - {s}_{i} ‖}_{2}^{2}$$

Using this actual motion path, the second optimization problem may then be written as:

$$[ \hat{x} ] = arg {min}_{x} \{ {‖ {E}_{\hat{θ}} x - s ‖}_{2}^{2} + λ {‖ x - {x}_{proc} ‖}_{2}^{2} \}$$

In this equation, \hat{x} corresponds to the second motion corrected image dataset that is to be determined by this optimization problem, x is the image dataset that is varied to solve this optimization problem, and x_{proc} is the processed image dataset. The weighting factor λ scales the influence of the algorithm for image quality improvement on the resulting image dataset. This factor may be chosen depending on the concrete application, e.g., by a user or a developer of the image processing algorithm, or it may be determined during a training process of the algorithm for image quality improvement. The encoding operator may be the only part of the problem that explicitly depends on the motion data.

The first optimization problem may minimize a measure for an inconsistency between the first motion corrected image dataset and the magnetic resonance data. The first optimization problem may therefore correspond to a minimization of the first summand given above. It may however be advantageous, when the first optimization problem minimizes a weighted sum of this measure and a regularization term that depends on the first motion corrected image dataset. The regularization term may include a measure for the noise in the first motion corrected image dataset.

The further optimization problem may minimize a weighted sum of a first summand and a second summand by varying the respective output motion corrected image dataset, wherein the first summand is a measure for an inconsistency between the respective output motion corrected image dataset and the magnetic resonance data, wherein this measure is determined under the assumption that the motion data describes the movement of the object during the acquisition of the magnetic resonance data, and wherein the second summand is a measure for an inconsistency between the respective output motion corrected image dataset and the respective further processed image dataset.

The optimization approach previously discussed with respect to the second optimization problem may therefore, additionally or alternatively, be used to implement the further optimization problem. For this purpose, the further processed image dataset for the respective iteration replaces the processed image dataset in the equation given above and the result of the minimization is the respective output motion corrected image dataset for the respective iteration. While the same weighting factor 2 may be used for each iteration and therefore for each one of the further optimization problems, it may be advantageous to use different weighting factors 2 for the different iterations.

The measure for the inconsistency between the second motion corrected image dataset and the magnetic resonance data may be determined as a measure for the difference between an at least partial representation of the magnetic resonance data and artificial measurement data generated by an application of an encoding operator on the second motion corrected image dataset.

Additionally, or alternatively, the measure for the inconsistency between the respective output motion corrected image dataset and the magnetic resonance data may be determined based on a difference between the at least partial representation of the magnetic resonance data and artificial measurement data generated by an application of the encoding operator on the respective output motion corrected image dataset.

As discussed above, this approach allows for a combination of an algorithm for image quality improvement with a motion correction based on a motion forward model implemented by the encoding operator. This may be used to implement a “SENSE plus motion forward model” approach. The respective encoding operator may depend on the motion data.

The at least a partial representation of the magnetic resonance data may be a vector that includes all measurements or at least the measurements that are not part of the scout measurement and/or the motion guidance lines that are used to determine the motion data.

The encoding operator may include a non-uniform Fourier-transform, wherein the non-uniform Fourier-transform is parametrized by the motion data. In the previous example for the encoding operator, it was assumed that explicit image transformations, namely translations T_{θ}_{ᵢ} and rotations R_{θ}_{ᵢ} in image space, are used to transform the second motion corrected image dataset and the respective output motion corrected image dataset. A rotation of an image dataset is however quite computationally expensive. Because such a rotation would need to be repeated during each iteration of the minimization, the computational requirements, in particular the time requirement, for the optimization may be noticeably reduced when such an explicit rotation is avoided. It was found that rotations and optionally also translations may be avoided in the previously discussed approach when the uniform Fourier-transform is replaced by a non-uniform Fourier-transform. In this case, it is sufficient to adjust the sampling pattern that is used during the Fourier-transform instead of using a full translation and/or rotation of the image dataset. The replacement of the explicit rotations by a non-uniform Fourier-transform did speed up the optimization by up to an order of magnitude in experiments performed during the development of the disclosure.

The algorithm for image quality improvement and/or the respective further algorithm for image quality improvement may include a respective trained machine learning model. The further algorithm for image quality improvement and/or the respective further algorithm for image quality improvement may especially be configured to compensate for a relatively sparse and/or uneven sampling of the k-space during the acquisition of the magnetic resonance data.

Such a sparse and/or uneven sampling may decrease the time requirement for the acquisition of the magnetic resonance data and therefore reduce the influence of a motion of the object on the image quality. On the other hand, such a sparse and/or uneven sampling of the k-space may however increase the noise floor and/or lead to the creation of certain image artifacts in the reconstructed image dataset. While it is in principle possible to alleviate some of these issues by manually designed algorithms, e.g., by using a lowpass filter to reduce noise, it was found that trained machine learning models may be especially appropriate for such a task.

A trained machine learning model may mimic cognitive functions that humans associate with other human minds. In particular, by a training based on training data the machine learning model is able to adapt to new circumstances and to detect and extrapolate patterns. Another term for “trained machine learning model” is “trained function.”

Parameters of a machine learning model may be configured by training. In particular, supervised training, semi-supervised training, unsupervised training, reinforcement learning, and/or active learning may be used. Furthermore, representation learning (an alternative term is “feature learning”) may be used. In particular, the parameters of machine learning models may be configured iteratively by several acts of training. In particular, within the training a certain cost function may be minimized. In particular, within the training of a neural network, the backpropagation algorithm may be used.

In particular, a machine learning model may include a neural network, a support vector machine, a decision tree, and/or a Bayesian network, and/or the machine learning model may be based on k-means clustering, Q-learning, genetic algorithms, and/or association rules. In particular, a neural network may be a deep neural network, a convolutional neural network, or a convolutional deep neural net-work. Furthermore, a neural network may be an adversarial network, a deep adversarial network, and/or a generative adversarial network.

In an embodiment, the algorithm for image quality improvement and/or at least one of the further algorithms for image quality improvement may be a convolutional neural network, e.g., having a U-Net structure. Additionally, or alternatively, the algorithm for image quality improvement and/or at least one of the further algorithms for image quality improvement may be a Transformer, e.g., a SWIN-Transformer or a Reformer.

The actual training of the algorithm for image quality improvement and/or of the respective further algorithm for image quality improvement may not be part of the computer-implemented method as described herein. The training may be performed in a preparatory act outside of the method itself, e.g., by the developer of a software product or a service that implements the computer-implemented method. Alternatively, the training may be performed as an additional act of the discussed method.

The disclosure also relates to a computer-implemented method for providing at least one trained machine learning model, wherein the respective trained machine learning model is trained to implement the algorithm for image quality improvement and/or the respective further algorithm for image quality improvement in the computer-implemented method for providing a final motion corrected image dataset. The method includes receiving multiple training datasets, wherein each training dataset includes input data for an overall machine learning model and, in particular, a reference image dataset that is related to the input data. The method further includes training the overall machine learning model based on the multiple training datasets to determine the trained overall machine learning model, such that the trained overall machine learning model includes: (1) a trained first partial machine learning model and at least one trained further partial machine learning model; and/or (2) multiple identical copies of the trained first partial machine learning model. The method further includes providing the trained first partial machine learning model as the algorithm for image quality improvement and/or providing the respective trained further partial machine learning model as the respective further algorithm for image quality improvement.

As discussed above, the computer-implemented method for providing a final motion corrected image dataset may use an iterative approach in which the output of the algorithm or the further algorithm for image quality improvement is reused as the input for the same algorithm or another one of the further algorithms for image quality improvement after an intermediate motion compensation act. By training the overall machine learning model, as discussed above, an end-to-end training of the overall algorithm may be achieved. The respective reference image dataset may depict a healthy person, a patient, and/or an inanimate object, e.g., a phantom.

When each training dataset includes input data and a reference image dataset, a supervised training may easily be implemented, wherein the respective input data is used as an input for the overall machine learning model and the training is configured to minimize the difference between the output of the overall machine learning model for the respective input data and the reference image dataset taken from the same training dataset as the input data. Various approaches for implementing such a supervised training are well known in the art and will therefore not be discussed in detail. It may be possible to use a backpropagation of error, e.g., using a gradient descent approach, in particular using the Adam optimizer.

The use of multiple identical copies of the trained first partial machine learning model within the trained overall machine learning model may be useful when the same algorithm for image quality improvement may be used in all or at least multiple iterations of the image quality improvement discussed above. This may be achieved by limiting the variation of the parameters, e.g., of the input weights of different neurons, of the overall machine learning model in such a way that these parameters are identical for all copies. Such a limitation may be useful to limit the number of parameters that need to be determined during the training. Such a limitation may speed up the training and/or allow for a training with a lower number of training datasets.

It may be advantageous to use mutually different algorithms for image quality improvement in at least some of the iterations and therefore to allow different parametrizations of the different partial machine learning models or to even use mutually different architectures for at least some of the partial machine learning models, e.g., when a sufficient amount of training data is available.

The input data and the reference image dataset for the respective training dataset may be based on the same k-space data, in particular on the same magnetic resonance data. The input data may be generated by only selecting data for a subgroup of the k-space points of this k-space data, e.g., by only incorporating data for every second or third point in a respective spatial direction. This may especially be used to simulate an undersampling of the k-space, e.g., in an accelerated magnetic resonance imaging. The input data may directly correspond to this undersampled k-space data and therefore, e.g., be simulated magnetic resonance data for an accelerated magnetic resonance imaging. Alternatively, the input data may be reconstructed from this undersampled k-space data. The reference image dataset may be reconstructed from the full k-space data. The respective input data and reference image dataset may be generated on the fly or in a preparation act before the beginning of method.

The overall machine learning model may be trained to provide an output based on undersampled k-space data or based on image data based thereon, which at least partially compensates an image degradation due to the undersampling.

When an algorithm for image quality improvement and/or a respective further algorithm for image quality improvement trained by the discussed method is used in the previously discussed computer-implemented method for providing a final motion corrected image dataset, features of the training implicitly determine features of the algorithm for image quality improvement and/or the respective further algorithm for image quality improvement, even when the actual training is performed outside of this method. Therefore, the discussed features of the training may limit the scope of the discussed computer-implemented method for providing a final motion corrected image dataset, even when the training itself is not part of that method. Features discussed with respect to the computer-implemented method for providing at least one trained machine learning model may be transferred to the computer-implemented method for providing a final motion corrected image dataset and vice-versa, to achieve the discussed advantages in the respective other method.

The trained overall machine learning model may be structured in such a way that the respective trained further partial machine learning model processes provided data that is based on respective output data provided by either the trained first partial machine learning model or by a different one of the respective trained further partial machine learning models. Alternatively, or additionally, the trained overall machine learning model may be structured such that all but one of the copies of the trained first partial machine learning model process provided data based on output data provided by another copy of the trained first partial machine learning model.

The respective input data may be based on or describe magnetic resonance data, wherein the trained overall machine learning model is structured in such a way that the respective provided data is provided by solving a respective optimization problem that depends on the magnetic resonance data and the respective output data.

The respective optimization problem may correspond to the second optimization problem or the further optimization problem in the computer-implemented method for providing a final motion corrected image dataset, wherein the motion data that parametrizes the second optimization problem or the further optimization problem is set to indicate no movement of the object during the acquisition of the magnetic resonance data.

In one example, this may be achieved by using the full computer-implemented method for providing a final motion corrected image dataset as the overall machine learning model with the modification of using fixed movement data that indicates no movement. This may be achieved in the example given above by setting the translations T_{θ}_{ᵢ} and rotations R_{θ}_{ᵢ} to unity. To reduce the computational load of the training, a modified encoding operator E_{θ} may however instead be used during the training, which is independent from the movement data and therefore, e.g., does not include T_{θ}_{ᵢ} and/or R_{θ}_{ᵢ}. Additionally, or alternatively, the modified encoding operator used during the training may use a uniform Fourier-transform that does not depend on the motion data instead of the non-uniform Fourier-transform discussed above.

In particular, the computer-implemented method for providing at least one trained machine learning model may therefore assume that the respective input data is motion free. Appropriate input data or reference data, on which such input data may be based, may be manually or automatically selected from a pool of possible input data or it may be specifically recorded for this purpose.

A training with motion free training data may be sufficient, because the trained models are to be used in the previously discussed computer-implemented method for providing a final motion corrected image dataset only after a motion correction is performed. Therefore, it may be assumed that only a relatively minor influence of motion remains in the data processed by the trained model.

Assuming motion free input may increase the speed of the training and may require less training data. In an alternative embodiment, it may be possible to introduce artificial motion by a further modification of the reference data to generate the input data. It may be possible to use motion free reference data that may represent magnetic resonance data from a multi-shot acquisition. The reference data may then be used to generate the reference image dataset. To generate the input data, patient motion between the shots may be simulated, which may be performed additionally or alternatively to the previously discussed discarding of some of the k-space points. When artificial movement is generated, appropriate motion data is already known and may be provided with the training dataset.

When the optimization problems are based on a weighted sum, e.g., one of the parameters λ as discussed above, the weights, e.g., the parameter λ, may be learned during the training or held at a fixed value.

Additionally, the disclosure relates to a data processing system configured to carry out the computer-implemented method for providing a final motion corrected image dataset and/or the computer-implemented method for providing at least one trained machine learning model. The data processing system may include a desktop computer or a server or it may be implemented as a cloud solution. Alternatively, the data processing system may be integrated into a medical imaging device. The data processing system may have hardware and/or software interfaces for receiving the various inputs and providing the outputs discussed above.

The disclosure also relates to a computer program that includes instructions configured to carry out the computer-implemented method for providing a final motion corrected image dataset and/or the computer-implemented method for providing at least one trained machine learning model, when the program is executed on a data processing system.

Additionally, the disclosure relates to a computer-readable medium including the computer program described herein.

Other objects and features of the present disclosure become apparent from the following detailed description considered in conjunction with the accompanying drawings. The drawings, however, are only principal sketches designed solely for the purpose of illustration and do not limit the disclosure.

### BRIEF DESCRIPTION OF THE DRAWINGS

FIG. 1 depicts a flowchart of an embodiment of the computer-implemented method for providing a final motion corrected image dataset.

FIG. 2 depicts an embodiment of the data processing system in a use case for the method according to FIG. 1.

FIG. 3 depicts relevant functions and data structures for an exemplary implementation of the second and the further optimization problems in FIG. 1.

FIG. 4 depicts an embodiment of the computer-implemented method for providing at least one trained machine learning model.

FIG. 5 depicts a possible architecture for the algorithms for image quality improvement trained in FIG. 4.

### DETAILED DESCRIPTION

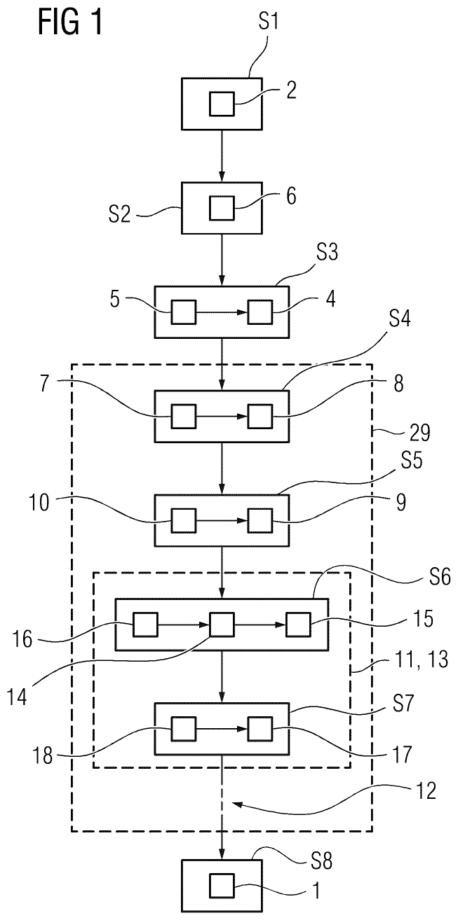

FIG. 1 shows a flowchart of a computer-implemented method for providing a final motion corrected image dataset 1 based on magnetic resonance data 2 concerning a person 3, in particular a patient. Additionally, or alternatively, the magnetic resonance data 2 may concern an object, e.g., an inanimate object and/or a person or patient. In the example, the method is configured to improve the image quality of the final motion corrected image dataset 1 by compensating for a movement of the object (e.g., person 3) and compensating for a sparse k-space sampling during the image acquisition.

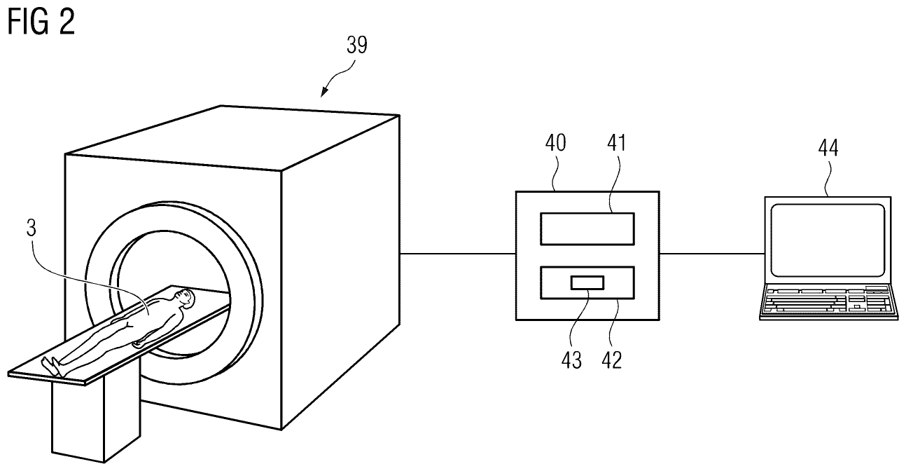

In the use case shown in FIG. 2, the magnetic resonance data 2 is directly provided to the data processing system 40 by a magnetic resonance imaging device 39 in act S1. It may also be possible to process previously acquired magnetic resonance data 2 stored in a database or taken from a different source.

In the example shown in FIG. 2, the data processing system 40 is implemented by a freely programmable data processing system 40, e.g., a server or a cloud solution. It may also be possible to integrate the data processing system 40 into the magnetic resonance imaging device 39 or to implement it within the workstation 44.

A computer program 43 implementing the acts of the method is stored in a memory 42 of the data processing system 2, which may also be understood to be a computer readable storage medium. The computer program is executed by the process of 41. In the example, the final motion corrected image dataset 1 is forwarded to the workstation 44 for visualization. It may also be possible to further process the final motion corrected image dataset 1, e.g., for an automatic feature recognition, and/or to store it in a storage device.

In the example, the measurement sequence used for acquiring the magnetic resonance data 2 is designed in such a way that for each shot a small part of the acquired magnetic resonance data is acquired during a very short time interval and may therefore be assumed to be motion free. This part of the magnetic resonance data may correspond to the motion guidance lines and/or a low-resolution scout scan \tilde{x} discussed above.

In act S2, motion data 6 that concerns a movement of the person 3 during the acquisition of the magnetic resonance data 2 is determined. In the example, the motion data 6 is determined based the motion guidance lines and/or a low-resolution scout scan \tilde{x} by determining an actual motion path \hat{θ}ᵢ for the respective shot i using the Formula:

$$[ {\hat{θ}}_{i} ] = arg {min}_{{θ}_{i}} ‖ {E}_{{θ}_{i}} \tilde{x} - {s}_{i} {‖}_{2}^{2}$$

as discussed above.

In act S3, a first motion corrected image dataset 4 is determined by solving a first optimization problem 5. The first optimization problem 5 depends on the magnetic resonance data 2 and on the motion data 6 and may be formulated as:

$$[ \hat{x} ] = arg {min}_{x} {‖ {E}_{\hat{θ}} x - s ‖}_{2}^{2} ,$$

wherein \tilde{x} corresponds to the first motion corrected image dataset 4, x is the image dataset that is varied to solve this optimization problem, and E_{\hat{θ}} is the encoding operator as discussed above in the context of the further optimization problem.

As already discussed, it may also be possible to add a regularization term to the first optimization problem.

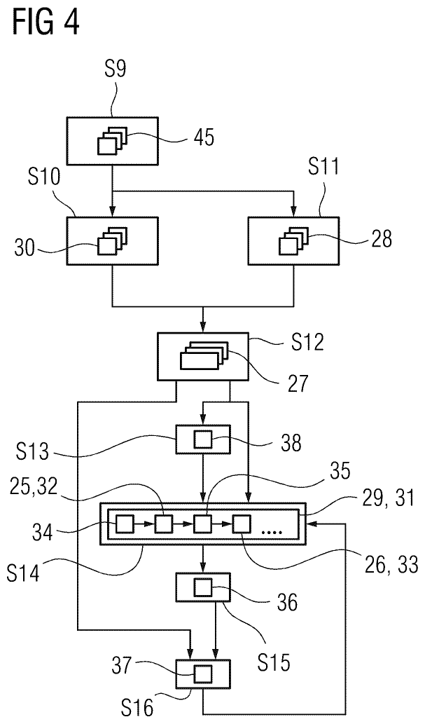

In act S4, the first motion corrected image dataset 4 is processed by an algorithm for image quality improvement 7 to provide a processed image dataset 8. As discussed in greater detail with reference to FIG. 4 below, the algorithm for image quality improvement 7 may be trained by machine learning. The algorithm for image quality improvement 7 is, in particular, designed and/or trained to compensate for the effects of the sparse k-space sampling.

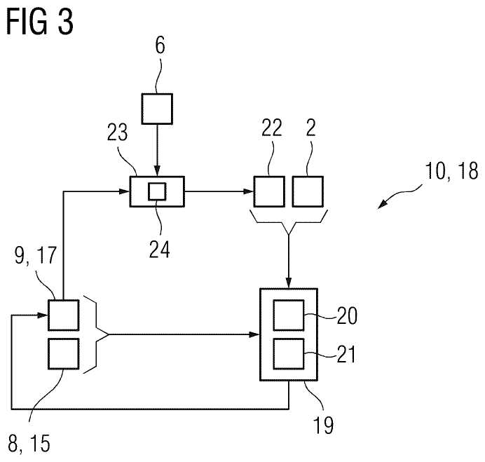

In act S5, a second motion corrected image dataset 9 is determined by solving a second optimization problem 10 that depends on the magnetic resonance data 2, on the motion data 6, and on the processed image dataset 8. A possible formulation of this optimization problem is provided herein. For completeness sake, a graphical representation of the structure of the second optimization problem 10 is given in FIG. 3. The same structure may also be used to implement the further optimization problem 18 discussed in greater detail below.

As indicated in FIG. 3, the second optimization problem 10, which is used in the example, minimizes a weighted sum 19 of a first summand 20 and a second summand 21 by varying the second motion corrected image dataset 9. The starting point for the variation may be the first motion corrected image dataset 4 or the processed image dataset 8. The optimization may be implemented using a gradient decent.

The first summand 20 is a measure for an inconsistency between the second motion corrected image dataset 9 and the magnetic resonance data 2. This measure is determined as a measure for the difference between an, in particular partial, representation of the magnetic resonance data 2 that may exclude the low-resolution scout and/or the motion guidance lines used to determine the motion data 6, and artificial measurement data 22 generated by an application of an encoding operator 23 on the second motion corrected image dataset 9.

As already discussed, the encoding operator 23 depends on the determined motion data 6. In the example shown in FIG. 2, the encoding operator 23 includes a non-uniform Fourier-transform 24 that may be used to encode the motion data without requiring an explicit rotation and/or translation.

The second summand 21 is a measure for an inconsistency between the second motion corrected image dataset 9 and the processed image dataset 8.

The resulting second motion corrected image dataset 9 may be provided as the final motion corrected image dataset 1. In certain examples, it may be advantageous to perform multiple iterations of an image quality improvement, as implemented in act S4, followed by a respective motion corrected reconstruction, as implemented by act S5.

In the example shown in FIG. 2, this is implemented by performing multiple iterations 11, 12 of a group 13 of acts including acts S6 and S7. For simplicity's sake, FIG. 1 only shows the first iteration 11 explicitly, indicating the further iterations 12 by a dashed line. While the multiple iterations 11, 12 may be implemented by a loop, it may be advantageous to unroll the loop, e.g., to allow for the use of different further algorithms for image quality improvement 14 in the different iterations.

In the respective act S6, a respective input motion corrected image dataset 16 is processed by a respective further algorithm for image quality improvement 14 to provide a respective further processed image dataset 15 for the respective iteration 11, 12. In other embodiments of the discussed method, it may also be possible to use the previously discussed algorithm for image quality improvement 7 in at least some of the iterations 11, 12.

In the first iteration 11 of the group 13 of acts, the second motion corrected image dataset 9 is used as the input motion corrected image dataset 16. In the further iterations 12, a respective output motion corrected image dataset 17 that was determined during the previous iteration 11, 12 is used as the respective input motion corrected image dataset 16.

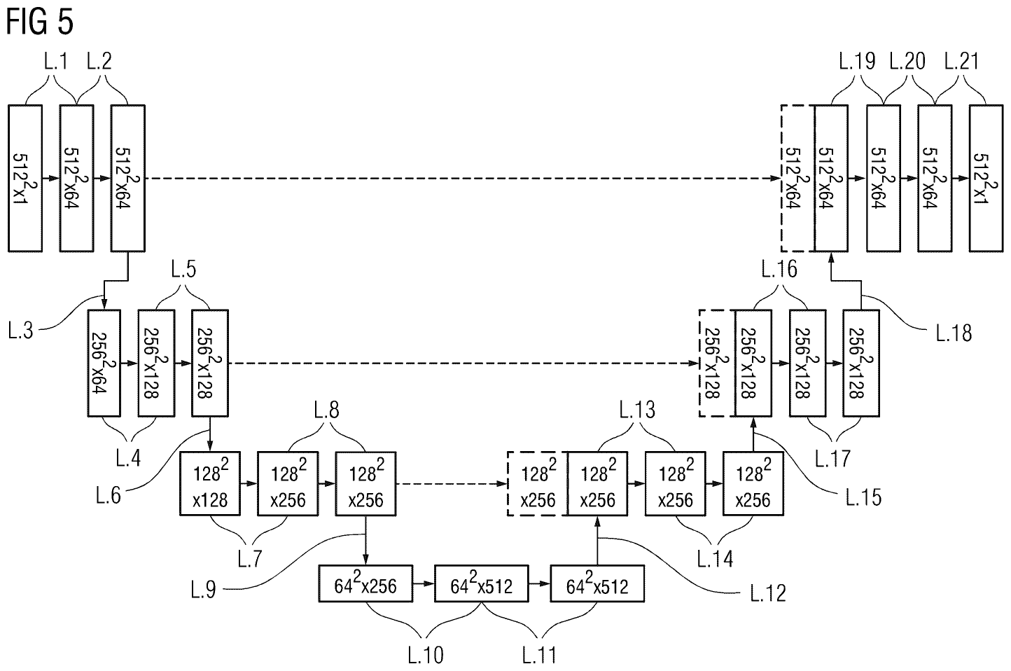

In the example, the respective algorithm for image quality improvement 7, 14 is implemented as a convolutional neural network, (e.g., having a U-net structure), as shown in FIG. 5. It may also be possible to use a manual parametrized algorithm, e.g., the lowpass filter, to improve the image quality in acts S4 and/or S6.

In the respective act S7, a respective output motion corrected image dataset 17 for the respective iteration 11, 12 is determined by solving a respective further optimization problem 18 that depends on the magnetic resonance data 2, on the motion data 6 and on the respective further processed image dataset 15 for the respective iteration 11, 12. A possible implementation of the optimization was already discussed with reference to FIG. 3 and the implementation of the second optimization problem 10. For implementing the further optimization problem 18, the respective output motion corrected image dataset 17 is used instead of the second motion corrected image dataset 9 and the respective further processed image dataset 15 is used instead of the processed image data set 8 in FIG. 3.

Once a given number of iterations 11, 12 are completed, the output motion corrected image dataset 17 determined in the last one of the iterations 11, 12 is provided as the final motion corrected image dataset 1 in act S8.

FIG. 4 shows a flow chart of an exemplary computer-implemented method for providing a respective trained machine learning model 25, 26 for the algorithm for image quality improvement 7 and the respective further algorithm for image quality improvement 14.

The acts S9 to S11 form preparatory acts for providing multiple training datasets 27 to be used during the training. In act S9, multiple sets of the reference data 45 are provided. The respective reference data 45 includes magnetic resonance data that was acquired under a relatively dense k-space sampling on persons and/or objects, e.g., on phantoms, with a negligible influence of patient or object movement.

In act S10, the respective reference image dataset 30 is reconstructed for each set of reference data 45. Such a reconstruction may correspond to the act S3 the FIG. 1, except for the absence of motion correction.

In act S11, measurement data for at least some of the sampling positions in k-space, e.g., each second or of 2 out of 3 points in each one of the phase encoding directions, is discarded to provide a set of input data 28 for each one of the sets of reference and data 45. Act S11 may therefore be considered to emulate an accelerated magnetic resonance measurement providing a sparser k-space sampling than the magnetic resonance imaging used to provide the respective set of reference data 45.

In act S12, multiple training datasets 27 are provided by combining the respective set of input data 28 and the respective reference image dataset 30 that are based on the same set of reference data 45.

The following acts will perform an iterative training of an overall machine learning model 29 based on these training datasets 27. In act S13, an initial reconstructed image 38 for the respective input data 28 is reconstructed. This reconstruction may correspond to the act S3 in FIG. 1, with the modification that no motion of the object (e.g., an inanimate object and/or a person/patient) is assumed.

In act S14, an overall machine learning model 29 is applied to the initial reconstructed image 38 to provide an output 36 of the overall machine learning model 29 in its current training state in act S15. During the first iteration of the training, the parameters of the overall machine learning model 29, e.g., input weights of various neurons, may be initialized to zero.

The overall machine learning model 29 is setup in such a way that, once the training is finished, the trained overall machine learning model 31 includes a trained first partial machine learning model 32 and at least one trained further partial machine learning model 33. The trained first partial machine learning model 32 may then implement the algorithm for image quality improvement 7 and the respective trained further partial machine learning model 33 may implement the respective further algorithm for image quality improvement 14. Therefore, the trained first partial machine learning model 32 and the at least one trained further partial machine learning model 33 may be provided as the trained machine learning models 25, 26.

Such an overall machine learning model 29 may be implemented by using the acts S4 to S7 in FIG. 1, including all of the iterations 11, 12, as the overall machine learning model 29. As already discussed, the movement data 6 may be set to represent no movement or the overall machine learning model 29 may be modified to, e.g., not include any operations that depend on the movement data 6.

By using such an overall model 29, the respective trained further partial machine learning model 33 will process provided data that is based on respective output data provided by either the trained first partial machine learning model 32 or by a different one of the respective trained further partial machine learning models 33. The respective provided data is provided by solving a respective optimization problem 34, 35. The optimization problems 34, 35 will correspond to the first and second optimization problem 10, 18 with the movement set to zero in this structure.

In act S16, the cost function 37 is evaluated by comparing the output to 36 with the reference image dataset 30 for the respective training dataset 27. The cost function 37 is then minimized by iteratively varying the parameters of the overall machine learning model 29. In the example, the Adam optimizer is used to adjust the parameters based on the cost function.

As already discussed, the same approach for training may also be used when multiple copies of the first partial machine learning model are used.

The respective trained machine learning model 25, 26 may be a convolutional neural network that may have a U-net structure. An exemplary structure of such a machine learning model is shown in FIG. 5. For simplicity's sake, the processing of two-dimensional image data sets is assumed. This structure may be extended to process three-dimensional image data sets or even higher dimensional image data sets.

The input data to the machine learning network is a two-dimensional medical image including 512×512 pixel, every pixel including one intensity value. The machine learning network includes convolutional layers (indicated by solid, horizontal arrows), pooling layers (indicating by solid arrows pointing down), and upsampling layers (indicated by solid arrows pointing up), the number of the respective nodes is indicated within the boxes. Within the U-net structure first the input images are downsampled (decreasing the size of the images and increasing the number of channels), afterwards they are upsampled (increasing the size of the images and decreasing the number of channels) to generate a transformed image.

All except the last convolutional layers L.1, L.2, L.4, L.5, L.7, L.8, L.10, L.11, L.13, L.14, L.16, L.17, L.19, L.20 use 3×3 kernels with a padding of 1, the ReLU activation function, and a number of filters/convolutional kernels that matches the number of channels of the respective node layers as indicated in FIG. 5. The last convolutional layer L.22 uses a 1×1 kernel with no padding and the ReLU activation function.

The pooling layers L.3, L.6, L.9 are max-pooling layers, replacing four neighboring nodes with only one node, the value being the maximum of the values of the four neighboring nodes. The upsampling layers L.12, L.15, L.18 are transposed convolution layers with 3×3 kernels and stride 2, which effectively quadruple the number of nodes. The dashed horizontal errors correspond to concatenation operations, where the output of a convolutional layer L.2, L.5, L.8 of the downsampling branch of the U-net structure is used as additional inputs for a convolutional layer L.13, L.16, L.19 of the upsampling branch of the U-net structure. This additional input data is treated as additional channels in the input node layer for the convolutional layer L.13, L.16, L.19 of the upsampling branch.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for providing a final motion corrected image dataset based on magnetic resonance data of an object, the computer-implemented method comprising:
receiving magnetic resonance data;
determining a first motion corrected image dataset by solving a first optimization problem, wherein the first optimization problem depends on the magnetic resonance data and on motion data, and wherein the motion data concerns a movement of the object during an acquisition of the magnetic resonance data;
processing the first motion corrected image dataset by an algorithm for image quality improvement to provide a processed image dataset;
determining a second motion corrected image dataset by solving a second optimization problem that depends on the magnetic resonance data, on the motion data, and on the processed image dataset; and
providing the second motion corrected image dataset as the final motion corrected image dataset or determining the final motion corrected image dataset based on the second motion corrected image dataset.

2. The computer-implemented method according to claim 1, wherein the determining of the final motion corrected image dataset comprises at least one iteration of:
processing a respective input motion corrected image dataset by the algorithm for image quality improvement or by a respective further algorithm for image quality improvement to provide a respective further processed image dataset for the respective iteration, wherein the second motion corrected image dataset is used as the input motion corrected image dataset in a first iteration, and wherein a respective output motion corrected image dataset determined during a previous iteration is used as the respective input motion corrected image dataset for the respective iteration in all iterations after the first iteration; and
determining a respective output motion corrected image dataset by solving a respective further optimization problem that depends on the magnetic resonance data, on the motion data, and on the respective further processed image dataset for the respective iteration,
wherein the output motion corrected image dataset determined in a last iteration of the at least one iteration is provided as the final motion corrected image dataset.

3. The computer-implemented method of claim 2, wherein the further optimization problem minimizes a weighted sum of a first summand and a second summand by varying the respective output motion corrected image dataset,
wherein the first summand comprises a measure for an inconsistency between the respective output motion corrected image dataset and the magnetic resonance data,
wherein the measure of the first summand is determined assuming that the motion data describes the movement of the object during the acquisition of the magnetic resonance data, and
wherein the second summand comprises a measure for an inconsistency between the respective output motion corrected image dataset and the respective further processed image dataset.

4. The computer-implemented method of claim 1, wherein the second optimization problem minimizes a weighted sum of a first summand and a second summand by varying the second motion corrected image dataset,
wherein the first summand comprises a measure for an inconsistency between the second motion corrected image dataset and the magnetic resonance data,
wherein the measure of the first summand is determined assuming that the motion data describes the movement of the object during the acquisition of the magnetic resonance data, and
wherein the second summand comprises a measure for an inconsistency between the second motion corrected image dataset and the processed image dataset.

5. The computer-implemented method of claim 4, wherein the further optimization problem minimizes a weighted sum of the first summand and the second summand by varying the respective output motion corrected image dataset.

6. The computer-implemented method of claim 4, wherein the measure of the first summand is determined: (1) as a difference between an at least partial representation of the magnetic resonance data and artificial measurement data generated by an application of an encoding operator on the second motion corrected image dataset, and/or (2) as a difference between the at least partial representation of the magnetic resonance data and artificial measurement data generated by an application of the encoding operator on the respective output motion corrected image dataset.

7. The computer-implemented method of claim 6, wherein the encoding operator comprises a non-uniform Fourier-transform, and
wherein the non-uniform Fourier-transform is parametrized by the motion data.

8. The computer-implemented method of claim 1, wherein the algorithm for image quality improvement comprises a respective trained machine learning model.

9. The computer-implemented method of claim 1, wherein the object is an inanimate object and/or a person.

10. A computer-implemented method for providing at least one trained machine learning model, wherein the at least one trained machine learning model is trained to implement an algorithm for image quality improvement, wherein the algorithm is used for processing a first motion corrected image dataset for the image quality improvement to provide a processed image dataset, the computer-implemented method comprising:
receiving multiple training datasets, wherein each training dataset of the multiple training datasets comprises input data for an overall machine learning model;
training the overall machine learning model based on the multiple training datasets to determine the trained overall machine learning model, such that the trained overall machine learning model comprises: (1) a trained first partial machine learning model and at least one trained further partial machine learning model; and/or (2) multiple identical copies of the trained first partial machine learning model; and
providing the trained first partial machine learning model as the algorithm for image quality improvement and/or providing the respective trained further partial machine learning model as a respective further algorithm for image quality improvement.

11. The computer-implemented method of claim 10, wherein the trained overall machine learning model is structured such that: (1) the respective trained further partial machine learning model processes provided data that is based on respective output data provided by either the trained first partial machine learning model or by a different respective trained further partial machine learning model; and/or (2) all but one copy of the trained first partial machine learning model process provided data based on output data provided by another copy of the trained first partial machine learning model.

12. The computer-implemented method of claim 11, wherein the respective input data is based on or describes magnetic resonance data, and
wherein the trained overall machine learning model is structured such that the respective provided data is provided by solving a respective optimization problem that depends on the magnetic resonance data and the respective output data.

13. The computer-implemented method of claim 12, wherein the respective optimization problem corresponds to a second optimization problem for determining a second motion corrected image dataset that depends on the magnetic resonance data, on the motion data, and on the processed image dataset,
wherein the motion data that parametrizes the second optimization problem is set to indicate no movement of an object during an acquisition of the magnetic resonance data.

14. A data processing system comprising:
at least one processor configured to:
receive magnetic resonance data;
determine a first motion corrected image dataset by solving a first optimization problem, wherein the first optimization problem depends on the magnetic resonance data and on motion data, and wherein the motion data concerns a movement of an object during an acquisition of the magnetic resonance data;
process the first motion corrected image dataset by an algorithm for image quality improvement to provide a processed image dataset;
determine a second motion corrected image dataset by solving a second optimization problem that depends on the magnetic resonance data, on the motion data, and on the processed image dataset; and
provide the second motion corrected image dataset as a final motion corrected image dataset or determine the provided final motion corrected image dataset based on the second motion corrected image dataset.
